(19) United States
(12) Patent Application Publication
(10) Pub. No.: US 2007/0188062 A1
(43) Pub. Date: Aug. 16, 2007

(54) Structures and methods for improving image quality of organic light emitting diodes integrated with color filters

(75) Inventors: Chun-Cheng Cheng, Pingtung County (TW); Yu-Jung Liu, Kaohsiung City (TW); Yung-Hui Yeh, Hsinchu City (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/511,463

(22) Filed: Aug. 29, 2006

(30) Foreign Application Priority Data
Feb. 10, 2006 (TW) 095104510

(51) Int. Cl. H01L 51/52; H01L 51/56

(52) U.S. Cl. 313/112; 313/506; 313/509; 257/98; 257/E51.002; 438/29

(57) ABSTRACT

Structures and methods for improving image quality of organic light emitting diode integrated with color filters, the structures and methods mainly utilize a planarization layer to be coated on the color filter or to substitute for a passivation layer, or utilize a planarization layer to be coated on the color filter and utilize another planarization layer to substitute for a passivation layer to effectively reduce surface roughness of pixel electrode, therefore manufacturing yield and image quality of the organic light emitting diode are improved.

### FIELD OF THE INVENTION

The present invention relates to structures and methods for improving image quality of organic light emitting diodes integrated with color filters, more particularly to structures and methods utilizing a planarization layer to be coated on the color filter or to substitute for a passivation layer, or utilizing a planarization layer to be coated on the color filter and utilize another planarization layer to substitute for a passivation layer to effectively reduce surface roughness of pixel electrode and improve manufacturing yield and image quality of the organic light emitting diode display.

### BACKGROUND OF THE INVENTION

The active matrix organic light emitting display (AMOLED) has developed from using RGB or RGBW light sources to a single white light source integrated with a color filter, thus resolution and size of the display has been greatly increased. The fabrication of an AMOLED integrated with a color filter usually utilizes a structure of color filter on-array (COA) and uses a white light source of bottom-emission organic light emitting diode (OLED). However, adding the step for manufacturing the color filter will increase roughness of subsequently deposited transparent pixel electrode and influence the uniformity for manufacturing the organic light emitting diode, thus manufacturing yield and image quality of the organic light emitting diode are decreased.

FIG. 1 shows a conventional structure of an organic light emitting diode integrated with a color filter, which is disclosed in U.S. Pat. No. 6,515,428 entitled “Pixel Structure of an Organic Light Emitting Diode Display Device and its Manufacturing Method.” In FIG. 1, a poly-silicon island 120 is formed on a substrate 110, an insulating oxide layer 130 is formed on the substrate 110 to cover the poly-silicon island 120, a gate metal layer 135 corresponding to the location of the poly-silicon island 120 is formed on the insulating oxide layer 130, a dielectric layer 140 is formed on the insulating oxide layer 130 to cover the gate metal layer 135, a metal layer 150 is formed on the dielectric layer 140 and a part of the metal layer 150 penetrates the dielectric layer 140 and the insulating oxide layer 130 to connect with the poly-silicon island 120, a color filter 160 is formed on the metal layer 150, and a transparent pixel electrode layer 170 is formed on the color filter 160. In this conventional structure, because the color filter 160 is coated on the metal layer 150, the surface of the color filter 160 will become very rough. The surface roughness is measured to be about 35 nm when the solvent is volatilized and the color filter 160 is solidified. The rough color filter 160 will cause roughness of the subsequently deposited transparent pixel electrode layer 170 and cause that the transparent pixel electrode layer 170 will easily get short circuits with a metal layer formed on an organic light emitting diode layer which is formed on the transparent pixel electrode layer 170 when the transparent pixel electrode layer 170 contacts with the organic light emitting diode layer. This phenomenon is also a main factor causing mura image and point defects of the pixels.

FIG. 2 shows another conventional structure of an organic light emitting diode integrated with a color filter. In FIG. 2, a poly-silicon island 220 is formed on a substrate 210, an insulating oxide layer 230 is formed on the substrate 210 to cover the poly-silicon island 220, a gate metal layer 235 corresponding to the location of the poly-silicon island 220 is formed on the insulating oxide layer 230, a color filter 240 is formed on the insulating oxide layer 230 to cover the gate metal layer 235, a metal layer 250 is formed on the color filter 240 and a part of the metal layer 250 penetrates the color filter 240 and the insulating oxide layer 230 to connect with the poly-silicon island 220, a passivation layer 260 is formed on the metal layer 250, and a transparent pixel electrode layer 270 is formed on the passivation layer 260. In this another conventional structure, the color filter 240 is utilized to directly substitute for the dielectric layer 140 in FIG. 1. Because the rough surface of the color filter 240 is still exists, short circuit condition between layers will occur easily in the subsequent manufacturing process. Therefore, image quality is still not good.

To solve the rough surface problem due to the process for manufacturing the color filter in prior art structure and method for organic light emitting diode integrated with a color filter, the present invention provides a structure and method for improving image quality of an organic light emitting diode integrated with a color filter, the structure and method mainly utilize a planarization layer to be coated on the color filter or to substitute for a passivation layer, or utilize a planarization layer to be coated on the color filter and utilize another planarization layer to substitute for a passivation layer to effectively reduce surface roughness of pixel electrode, therefore manufacturing yield and image quality of the organic light emitting diode are improved.

### SUMMARY OF THE INVENTION

The primary objective of the present invention is to provide a structure for improving image quality of an organic light emitting diode integrated with a color filter, so as to effectively reduce surface roughness of pixel electrode, therefore manufacturing yield and image quality of the organic light emitting diode are improved.

The secondary objective of the present invention is to provide a method for improving image quality of an organic light emitting diode integrated with a color filter, so as to effectively reduce surface roughness of pixel electrode, therefore manufacturing yield and image quality of the organic light emitting diode are improved.

To achieve the foregoing objectives, the present invention provides a structure and method for improving image quality of an organic light emitting diode integrated with a color filter, the structure and method mainly utilize a planarization layer to be coated on the color filter or to substitute for a passivation layer, or utilize a planarization layer to be coated on the color filter and utilize another planarization layer to substitute for a passivation layer to effectively reduce surface roughness of pixel electrode, therefore manufacturing yield and image quality of the organic light emitting diode are improved.

To make the examiner easier to understand the objectives, structure, innovative features, and function of the invention, preferred embodiments together with accompanying drawings are illustrated for the detailed description of the invention.

### BRIEF DESCRIPTION OF THE DRAWINGS

FIG. 1 is a structure diagram of a prior art organic light emitting diode integrated with a color filter.

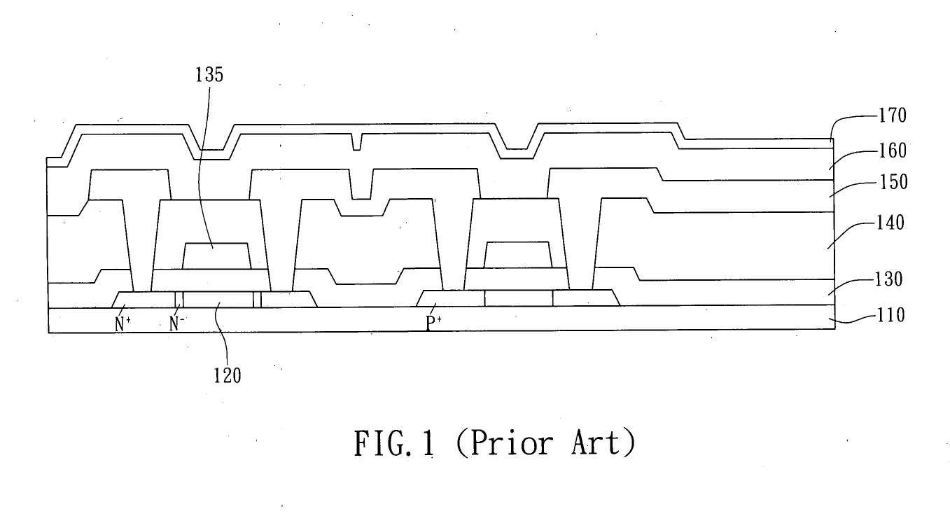

FIG. 2 is a structure diagram of another prior art organic light emitting diode integrated with a color filter.

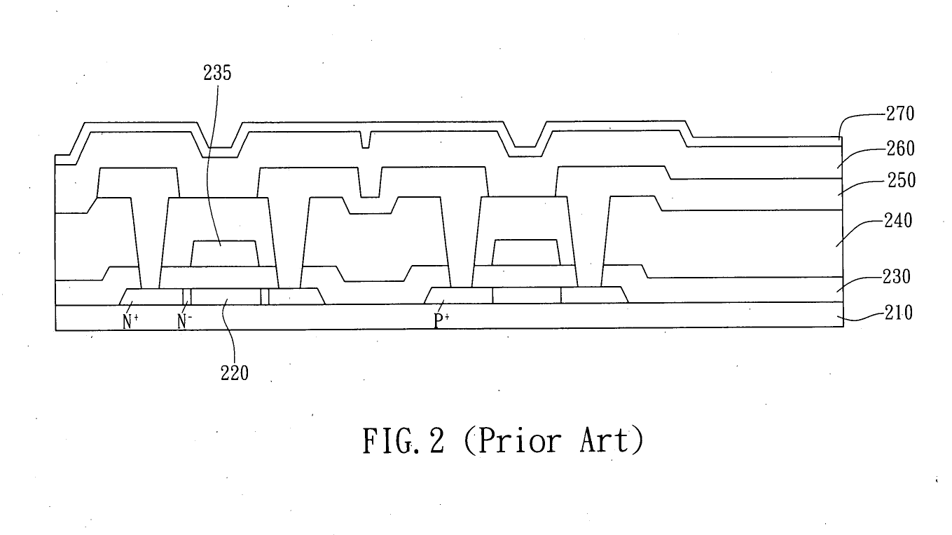

FIG. 3 is a structure diagram of the first embodiment of organic light emitting diode integrated with a color filter of the present invention.

FIG. 4 is a structure diagram of the second embodiment of organic light emitting diode integrated with a color filter of the present invention.

FIG. 5 is a structure diagram of the third embodiment of organic light emitting diode integrated with a color filter of the present invention.

### DESCRIPTION OF THE PREFERRED EMBODIMENT

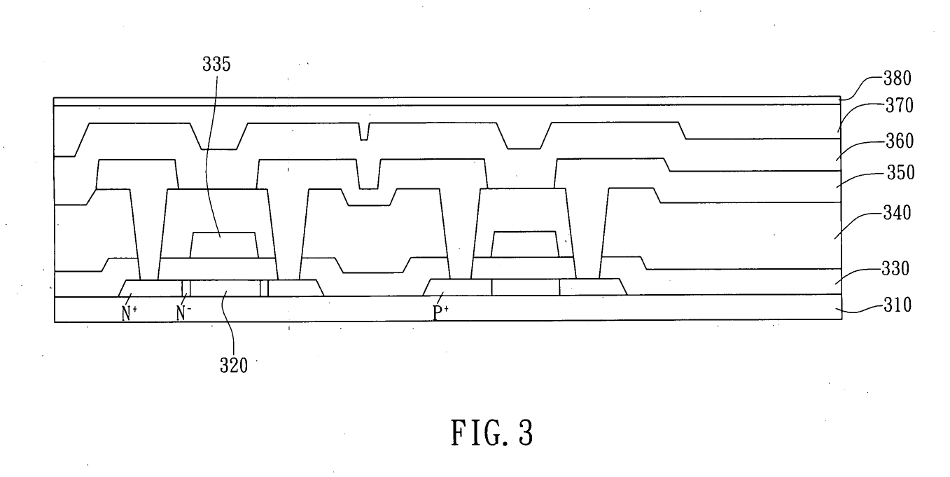

FIG. 3 is a structure diagram of the first embodiment of the present invention for improving image quality of an organic light emitting diode integrated with a color filter. In FIG. 3, a poly-silicon island 320 is formed on a substrate 310, an insulating oxide layer 330 is formed on the substrate 310 to cover the poly-silicon island 320, a gate metal layer 335 corresponding to the location of the poly-silicon island 320 is formed on the insulating oxide layer 330, a dielectric layer 340 is formed on the insulating oxide layer 330 to cover the gate metal layer 335, a metal layer 350 is formed on the dielectric layer 340 and a part of the metal layer 350 penetrates the dielectric layer 340 and the insulating oxide layer 330 to connect with the poly-silicon island 320, a color filter 360 is formed on the metal layer 350, a planarization layer 370 of photosensitive material is coated on the color filter 360, and a transparent pixel electrode layer 380 is formed on the planarization layer 370. The structure of the first embodiment of the present invention can be used to improve that of the above-mentioned prior US patent. By coating a planarization layer on the color filter, surface roughness of the first embodiment of the present invention can be greatly reduced thus image quality of the organic light emitting diode is improved.

The method of manufacturing the first embodiment of the present invention for improving image quality of an organic light emitting diode integrated with a color filter, comprising the following steps:
providing a substrate;
forming a poly-silicon island on the substrate;
forming an insulating oxide layer on the substrate to cover the poly-silicon island;
forming a gate metal layer corresponding to the location of the poly-silicon island on the insulating oxide layer;
forming a dielectric layer on the insulating oxide layer to cover the gate metal layer;
forming multiple contact windows on the dielectric layer, wherein the contact windows penetrate the dielectric layer and the insulating oxide layer;
forming a metal layer on the dielectric layer, wherein a part of the metal layer fills the contact windows and penetrates the dielectric layer and the insulating oxide layer to connect with the poly-silicon island;
forming a color filter on the metal layer;
coating a planarization layer on the color filter; and
forming a transparent pixel electrode layer on the planarization layer.

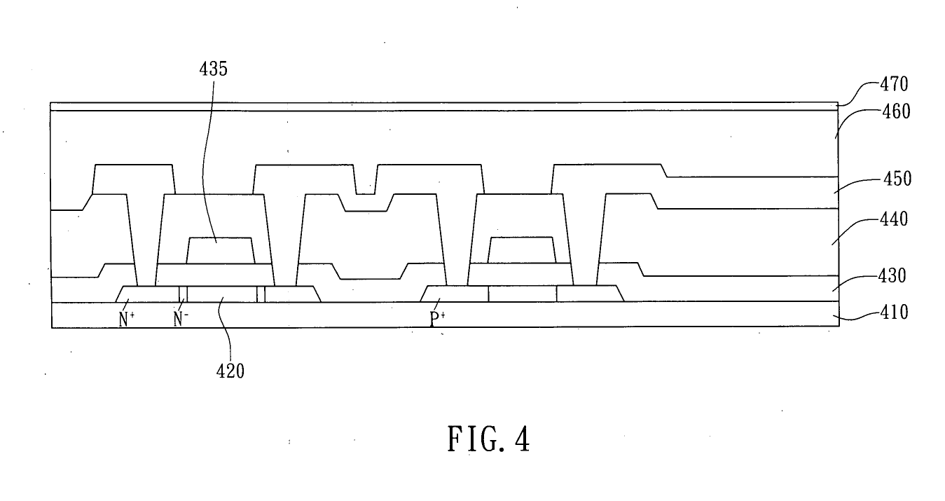

FIG. 4 is a structure diagram of the second embodiment of the present invention for improving image quality of an organic light emitting diode integrated with a color filter. In FIG. 4, a poly-silicon island 420 is formed on a substrate 410, an insulating oxide layer 430 is formed on the substrate 410 to cover the poly-silicon island 420, a gate metal layer 435 corresponding to the location of the poly-silicon island 420 is formed on the insulating oxide layer 430, a color filter 440 is formed on the insulating oxide layer 430 to cover the gate metal layer 435, a metal layer 450 is formed on the color filter 440 and a part of the metal layer 450 penetrates the color filter 440 and the insulating oxide layer 430 to connect with the poly-silicon island 420, a planarization layer 460 of photosensitive material is coated on the metal layer 450, and a transparent pixel electrode layer 470 is formed on the planarization layer 460. The structure of the second embodiment of the present invention can be used to improve that of the above-mentioned another prior art. By coating a planarization layer to directly substitute for the passivation layer, surface roughness of the second embodiment of the present invention can be greatly reduced thus image quality of the organic light emitting diode is improved.

The method of manufacturing the second embodiment of the present invention for improving image quality of an organic light emitting diode integrated with a color filter, comprising the following steps:
providing a substrate;
forming a poly-silicon island on the substrate;
forming an insulating oxide layer on the substrate to cover the poly-silicon island;
forming a gate metal layer corresponding to the location of the poly-silicon island on the insulating oxide layer;
forming a color filter on the insulating oxide layer to cover the gate metal layer;
forming multiple contact windows on the color filter, wherein the contact windows penetrate the color filter and the insulating oxide layer;
forming a metal layer on the color filter, wherein a part of the metal layer fills the contact windows and penetrates the color filter and the insulating oxide layer to connect with the poly-silicon island;
coating a planarization layer on the metal layer; and
forming a transparent pixel electrode layer on the planarization layer.

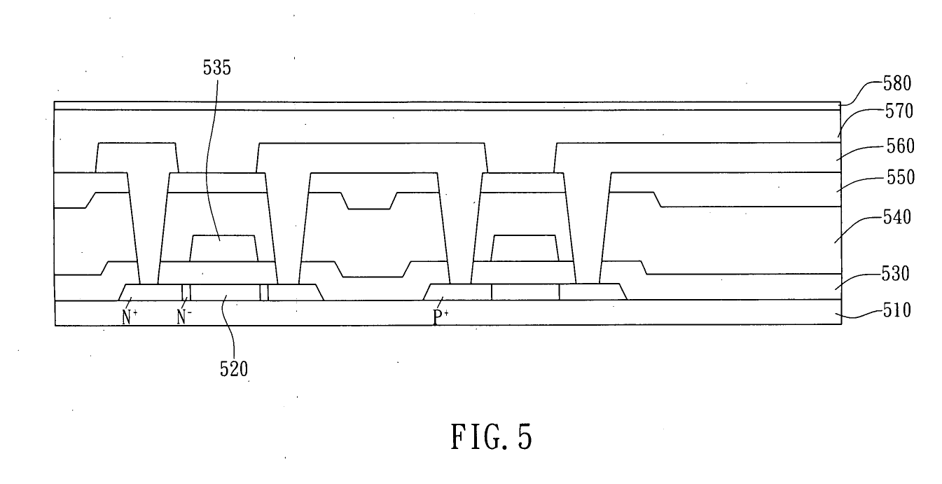

FIG. 5 is a structure diagram of the third embodiment of the present invention for improving image quality of an organic light emitting diode integrated with a color filter. In FIG. 5, a poly-silicon island 520 is formed on a substrate 510, an insulating oxide layer 530 is formed on the substrate 510 to cover the poly-silicon island 520, a gate metal layer 535 corresponding to the location of the poly-silicon island 520 is formed on the insulating oxide layer 530, a color filter 540 is formed on the insulating oxide layer 530 to cover the gate metal layer 535, a first planarization layer 550 of photosensitive material is coated on the color filter 540, a metal layer 560 is formed on the first planarization layer 550 and a part of the metal layer 560 penetrates the first planarization layer 550, the color filter 540 and the insulating oxide layer 530 to connect with the poly-silicon island 520, a second planarization layer 570 of photosensitive material is coated on the metal layer 560, and a transparent pixel electrode layer 580 is formed on the second planarization layer 570. The structure of the third embodiment of the present invention also can be used to improve that of the above-mentioned another prior art. By a two-step planarization, i.e. coating a first planarization layer on the color filter and coating a second planarization layer to directly substitute for the passivation layer, surface with severe roughness of the third embodiment of the present invention can be greatly reduced thus image quality of the organic light emitting diode is improved.

The method of manufacturing the third embodiment of the present invention for improving image quality of an organic light emitting diode integrated with a color filter, comprising the following steps:
providing a substrate;
forming a poly-silicon island on the substrate;
forming an insulating oxide layer on the substrate to cover the poly-silicon island;
forming a gate metal layer corresponding to the location of the poly-silicon island on the insulating oxide layer;
forming a color filter on the insulating oxide layer to cover the gate metal layer;
coating a first planarization layer on the color filter;
forming multiple contact windows on the first planarization layer, wherein the contact windows penetrate the first planarization layer, the color filter and the insulating oxide layer;
forming a metal layer on the first planarization layer, wherein a part of the metal layer fills the contact windows and penetrates the first planarization layer, the color filter and the insulating oxide layer to connect with the poly-silicon island;
coating a second planarization layer on the metal layer; and
forming a transparent pixel electrode layer on the second planarization layer.

In addition, the planarization layer coated in the invention is a photosensitive material which can be made of an organic material or an inorganic material. The dielectric layer also can be made of an organic material or an inorganic material. The substrate can be made of plastic, glass, quartz, or silicon wafer. The invention can be applied in the pixel structure of a N-type, P-type or CMOS thin film transistor and the thin film transistor can be an amorphous silicon thin film transistor, microcrystalline silicone thin film transistor or poly-silicon thin film transistor. Furthermore, according to the process of planarization layer of the invention, the surface roughness of the planarization layers 370, 460 and 570 are measured to be about 1.14 nm. Therefore, comparing with the surface roughness of the color filter in the prior US patent are measured to be about 35 nm, the subject invention actually and effectively reduces surface roughness of the pixel electrode, and thus improves manufacturing yield and image quality of the organic light emitting diode.

In summary, the present invention provides a structure and method for improving image quality of an organic light emitting diode integrated with a color filter, the structure and method mainly utilize a planarization layer to be coated on the color filter or to substitute for a passivation layer, or utilize a planarization layer to be coated on the color filter and utilize another planarization layer to substitute for a passivation layer to effectively reduce surface roughness of pixel electrode, therefore manufacturing yield and image quality of the organic light emitting diode are improved.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A structure for improving image quality of an organic light emitting diode integrated with a color filter, comprising:
a substrate;
a poly-silicon island formed on the substrate;
an insulating oxide layer formed on the substrate to cover the poly-silicon island;
a gate metal layer corresponding to the location of the poly-silicon island formed on the insulating oxide layer;
a dielectric layer formed on the insulating oxide layer to cover the gate metal layer, wherein multiple contact windows are formed on the dielectric layer and the contact windows penetrate the dielectric layer and the insulating oxide layer;
a metal layer formed on the dielectric layer, wherein a part of the metal layer fills the contact windows and penetrates the dielectric layer and the insulating oxide layer to connect with the poly-silicon island;
a color filter formed on the metal layer;
a planarization layer coated on the color filter; and
a pixel electrode layer formed on the planarization layer.

2. The structure for improving image quality of an organic light emitting diode integrated with a color filter of claim 1, wherein the planarization layer is a photosensitive material and the photosensitive material is made of an organic material or an inorganic material.

3. The structure for improving image quality of an organic light emitting diode integrated with a color filter of claim 1, wherein the dielectric layer is made of an organic material or an inorganic material.

4. The structure for improving image quality of an organic light emitting diode integrated with a color filter of claim 1, wherein the substrate is made of plastic, glass, quartz, or silicon wafer.

5. The structure for improving image quality of an organic light emitting diode integrated with a color filter of claim 1, wherein the structure is applied in a pixel structure of a N-type, P-type or CMOS thin film transistor.

6. The structure for improving image quality of an organic light emitting diode integrated with a color filter of claim 5, wherein the thin film transistor is an amorphous silicon thin film transistor, microcrystalline silicone thin film transistor or poly-silicon thin film transistor.

7. A method for improving image quality of an organic light emitting diode integrated with a color filter, comprising:
providing a substrate;
forming a poly-silicon island on the substrate;
forming an insulating oxide layer on the substrate to cover the poly-silicon island;
forming a gate metal layer corresponding to the location of the poly-silicon island on the insulating oxide layer;
forming a dielectric layer on the insulating oxide layer to cover the gate metal layer;
forming multiple contact windows on the dielectric layer, wherein the contact windows penetrate the dielectric layer and the insulating oxide layer;
forming a metal layer on the dielectric layer, wherein a part of the metal layer fills the contact windows and penetrates the dielectric layer and the insulating oxide layer to connect with the poly-silicon island;
forming a color filter on the metal layer;
coating a planarization layer on the color filter; and
forming a transparent pixel electrode layer on the planarization layer.

8. The method for improving image quality of an organic light emitting diode integrated with a color filter of claim 7, wherein the planarization layer is a photosensitive material and the photosensitive material is made of an organic material or an inorganic material, the dielectric layer is made of an organic material or an inorganic material, and the substrate is made of plastic, glass, quartz, or silicon wafer.

9. The method for improving image quality of an organic light emitting diode integrated with a color filter of claim 7, wherein the method is applied in a pixel structure of a N-type, P-type or CMOS thin film transistor and the thin film transistor is an amorphous silicon thin film transistor, microcrystalline silicone thin film transistor or poly-silicon thin film transistor.

10. A structure for improving image quality of an organic light emitting diode integrated with a color filter, comprising:
a substrate;
a poly-silicon island formed on the substrate;
an insulating oxide layer formed on the substrate to cover the poly-silicon island;
a gate metal layer corresponding to the location of the poly-silicon island formed on the insulating oxide layer;
a color filter formed on the insulating oxide layer to cover the gate metal layer, wherein multiple contact windows are formed on the color filter and the contact windows penetrate the color filter and the insulating oxide layer;
a metal layer formed on the color filter, wherein a part of the metal layer fills the contact windows and penetrates the color filter and the insulating oxide layer to connect with the poly-silicon island;
a planarization layer coated on the metal layer; and
a pixel electrode layer formed on the planarization layer.

11. The structure for improving image quality of an organic light emitting diode integrated with a color filter of claim 10, wherein the planarization layer is a photosensitive material and the photosensitive material is made of an organic material or an inorganic material.

12. The structure for improving image quality of an organic light emitting diode integrated with a color filter of claim 10, wherein the substrate is made of plastic, glass, quartz, or silicon wafer.

13. The structure for improving image quality of an organic light emitting diode integrated with a color filter of claim 10, wherein the structure is applied in a pixel structure of a N-type, P-type or CMOS thin film transistor.

14. The structure for improving image quality of an organic light emitting diode integrated with a color filter of claim 13, wherein the thin film transistor is an amorphous silicon thin film transistor, microcrystalline silicone thin film transistor or poly-silicon thin film transistor.

15. A method for improving image quality of an organic light emitting diode integrated with a color filter, comprising:
providing a substrate;
forming a poly-silicon island on the substrate;
forming an insulating oxide layer on the substrate to cover the poly-silicon island;
forming a gate metal layer corresponding to the location of the poly-silicon island on the insulating oxide layer;
forming a color filter on the insulating oxide layer to cover the gate metal layer;
forming multiple contact windows on the color filter, wherein the contact windows penetrate the color filter and the insulating oxide layer;
forming a metal layer on the color filter, wherein a part of the metal layer fills the contact windows and penetrates the color filter and the insulating oxide layer to connect with the poly-silicon island;
coating a planarization layer on the metal layer; and
forming a pixel electrode layer on the planarization layer.

16. The method for improving image quality of an organic light emitting diode integrated with a color filter of claim 15, wherein the planarization layer is a photosensitive material and the photosensitive material is made of an organic material or an inorganic material, the dielectric layer is made of an organic material or an inorganic material, and the substrate is made of plastic, glass, quartz, or silicon wafer.

17. The method for improving image quality of an organic light emitting diode integrated with a color filter of claim 15, wherein the method is applied in a pixel structure of a N-type, P-type or CMOS thin film transistor and the thin film transistor is an amorphous silicon thin film transistor, microcrystalline silicone thin film transistor or poly-silicon thin film transistor.

18. A structure for improving image quality of an organic light emitting diode integrated with a color filter, comprising:
a substrate;
a poly-silicon island formed on the substrate;
an insulating oxide layer formed on the substrate to cover the poly-silicon island;
a gate metal layer corresponding to the location of the poly-silicon island formed on the insulating oxide layer;
a color filter formed on the insulating oxide layer to cover the gate metal layer;
a first planarization layer coated on the color filter, wherein multiple contact windows are formed on the first planarization layer and the contact windows penetrate the first planarization layer, the color filter and the insulating oxide layer;
a metal layer formed on the first planarization layer, wherein a part of the metal layer fills the contact windows and penetrates the first planarization layer, the color filter and the insulating oxide layer to connect with the poly-silicon island;
a second planarization layer coated on the metal layer; and
a pixel electrode layer formed on the second planarization layer.

19. The structure for improving image quality of an organic light emitting diode integrated with a color filter of claim 18, wherein the first planarization layer and the second planarization layer are photosensitive materials and the photosensitive materials are made of an organic material or an inorganic material.

20. The structure for improving image quality of an organic light emitting diode integrated with a color filter of claim 18, wherein the substrate is made of plastic, glass, quartz, or silicon wafer.

21. The structure for improving image quality of an organic light emitting diode integrated with a color filter of claim 18, wherein the structure is applied in a pixel structure of a N-type, P-type or CMOS thin film transistor.

22. The structure for improving image quality of an organic light emitting diode integrated with a color filter of claim 21, wherein the thin film transistor is an amorphous silicon thin film transistor, microcrystalline silicone thin film transistor or poly-silicon thin film transistor.

23. A method for improving image quality of an organic light emitting diode integrated with a color filter, comprising:
providing a substrate;
forming a poly-silicon island on the substrate;
forming an insulating oxide layer on the substrate to cover the poly-silicon island;
forming a gate metal layer corresponding to the location of the poly-silicon island on the insulating oxide layer;
forming a color filter on the insulating oxide layer to cover the gate metal layer;
coating a first planarization layer on the color filter;
forming multiple contact windows on the first planarization layer, wherein the contact windows penetrate the first planarization layer, the color filter and the insulating oxide layer;
forming a metal layer on the first planarization layer, wherein a part of the metal layer fills the contact windows and penetrates the first planarization layer, the color filter and the insulating oxide layer to connect with the poly-silicon island;
coating a second planarization layer on the metal layer; and
forming a pixel electrode layer on the second planarization layer.

24. The method for improving image quality of an organic light emitting diode integrated with a color filter of claim 23, wherein the planarization layer is a photosensitive material and the photosensitive material is made of an organic material or an inorganic material, the dielectric layer is made of an organic material or an inorganic material, and the substrate is made of plastic, glass, quartz, or silicon wafer.

25. The method for improving image quality of an organic light emitting diode integrated with a color filter of claim 23, wherein the method is applied in a pixel structure of a N-type, P-type or CMOS thin film transistor and the thin film transistor is an amorphous silicon thin film transistor, microcrystalline silicone thin film transistor or poly-silicon thin film transistor.
